(19) United States
(12) Patent Application Publication
(10) Pub. No.: US 2008/0067652 A1
(43) Pub. Date: Mar. 20, 2008

(54) INTEGRATED MEMS PACKAGING

(75) Inventors: Stephane MENARD, KIRKLAND (CA); Jun LU, LASALLE (CA)

Correspondence Address: OGILVY RENAULT LLP, 1981 MCGILL COLLEGE AVENUE, SUITE 1600, MONTREAL, QC, H3A2Y3, US

(73) Assignee: SIMPLER NETWORKS INC., DORVAL (CA)

(21) Appl. No.: 11/532,676

(22) Filed: Sep. 18, 2006

(51) Int. Cl. H01L 23/02

(52) U.S. Cl. 257/678

(57) ABSTRACT

A micro-electromechanical systems (MEMS) package that includes a substrate onto which is disposed or otherwise formed an active MEMS device, a first barrier wall for preventing sealant from contaminating the MEMS device, a second barrier wall for preventing sealant from contaminating unintended areas of the substrate, and a cap for hermetically sealing the MEMS package with a particular gas or mixtures thereof which enhance the MEMS performance.

### FIELD OF THE INVENTION

This invention relates generally to the field of integrated circuit packaging and in particular to an integrated package for chip level MEMS devices.

### BACKGROUND OF THE INVENTION

Packaging of electrical circuits is a key element in the technological development of any device containing electrical components. With microelectromechanical systems (MEMS), the packaging is critically important as oftentimes it must provide for the isolation of a functional element, such as a circuit or actuator, from its environment.

More particularly, because MEMS devices tend to have moving parts, they typically cannot be packaged in the same manner used for purely electronic components. Instead, a hermetically sealed enclosure or “cavity” is oftentimes formed around the MEMS device itself.

One challenge in creating MEMS packages therefore, is to create this hermetically sealed cavity and provide one or more external electrical connections thereto while—at the same time—not damaging the microelectromechanical structures contained therein.

### SUMMARY OF THE INVENTION

In accordance with the principles of the invention, an integrated package for a MEMS or other device is achieved through the use of a pair of perimeter barrier walls surrounding a MEMS device disposed upon or part of a substrate, and a mating cap. Advantageously, the present invention provides mechanical robustness, a hermetic seal, ease of fabrication and low probability of damage/contamination to the packaged MEMS.

In accordance with yet another aspect of the present invention, the MEMS device is hermetically sealed in an environment containing an electronegative gas or gases, either alone or in combination with other electronegative gases or other inert gases.

### BRIEF DESCRIPTION OF THE DRAWING

In the drawing:

FIG. 1(A) is a perspective view of an assembled MEMS package according to the present invention;

FIG. 1(B) is a side view of the MEMS package of FIG. 1(A);

FIG. 2(A) is a partially-exploded-perspective view of the MEMS package according to the present invention;

FIG. 2(B) is a side view of the MEMS package of FIG. 2(A);

FIG. 3(A) is a fully-exploded-view of the MEMS package according to the present invention; and

FIG. 3(B) is a side view of the MEMS package of FIG. 3(A).

### DETAILED DESCRIPTION

The following merely illustrates the principles of the invention. It will thus be appreciated that those skilled in the art will be able to devise various arrangements which, although not explicitly described or shown herein, embody the principles of the invention and are included within its spirit and scope.

Furthermore, all examples and conditional language recited herein are principally intended expressly to be only for pedagogical purposes to aid the reader in understanding the principles of the invention and the concepts contributed by the inventor(s) to furthering the art, and are to be construed as being without limitation to such specifically recited examples and conditions.

Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Thus, for example, it will be appreciated by those skilled in the art that the diagrams herein represent conceptual views of illustrative structures embodying the principles of the invention.

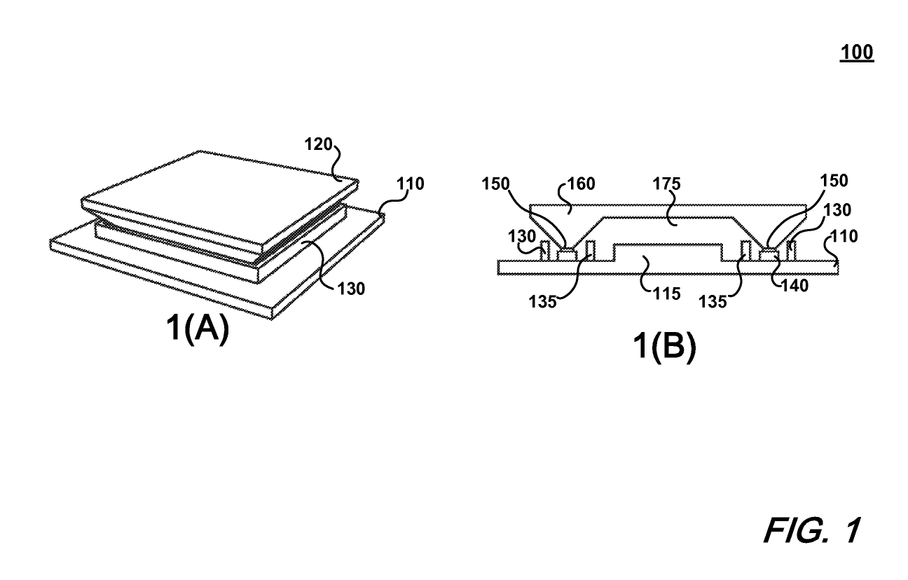

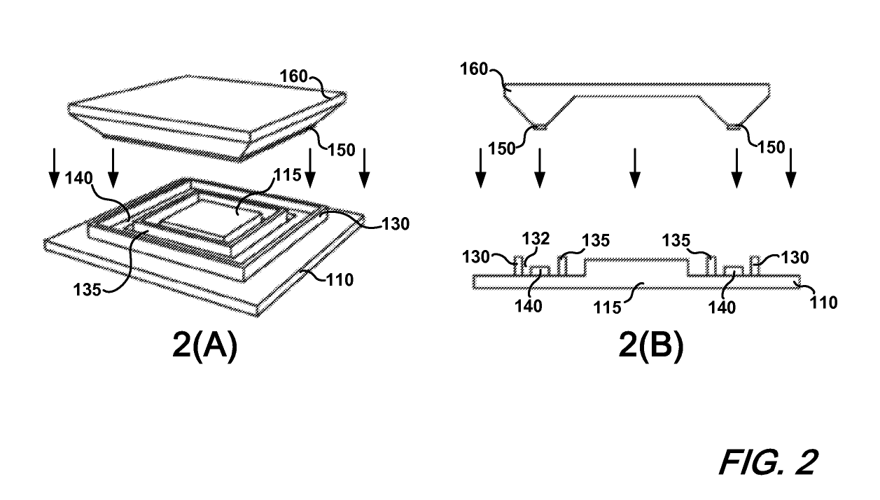

FIG. 1(A) is a perspective view of a MEMS package 100 according to the present invention. FIG. 1(B) is a side view of that same package 100. With simultaneous reference to FIGS. 1(A) and 1(B), there is shown a MEMS device 115 disposed upon an upper surface of, or alternatively formed as part of a substrate 110. Inner barrier wall 135 and outer barrier wall 130 are disposed upon the upper surface of the substrate 110.

While not specifically shown in FIGS. (1A) or 1(B), in a preferred embodiment the inner barrier wall 135 completely surrounds the perimeter of the MEMS device 115. Similarly, the outer barrier wall 130, completely surrounds the perimeter of the inner barrier wall 135.

As can be appreciated by those skilled in the art, the resulting structure has the MEMS device 115 innermost, an inner barrier wall 135 surrounding the perimeter of the MEMS device 115, and an outer barrier wall 130 surrounding the perimeter of the inner barrier wall 135. The relative position of the two barrier walls define a “gap” or “moat” 132 between the two walls.

According to the present invention, the depth and width of the gap or moat is variable—depending upon the particular application. Furthermore, while the gap is shown having a uniform width, it could nevertheless have a variable width as one traverses its perimeter and such variations are well within the contemplations of the present invention.

Disposed within the moat 132 is bonding block 140 to which the package cover or “cap” 160 is bonded through the effect of bonding material 150. Accordingly, and according to the present invention, when the cap 160 is affixed a perimeter seal is created as the cap 160 is bonded by the bonding material 150 to the bonding block 140.

When positioned in this manner, a space or “cavity” 175 is created in an area proximate to the MEMS chip 115. As we will discuss later and according to the present invention—this cavity 175 is preferably filled with one or more strongly-electronegative gasses or a mixture thereof. Advantageously, the perimeter seal formed by the cap 160 and the bonding block 140 through the effect of the bonding material 150, seals the electronegative gas(ses) within the cavity 175, permanently.

Of further advantage, and according to the present invention, the two barrier walls 130, 135 serve to contain the bonding material within the moat 132 as the cap 160 is pressed into place. As can be appreciated by those skilled in the art, placing the cap 160 onto the bonding block 140 acts to “squeeze” or compress some of the bonding material 150. Absent one or both of the barrier walls 130, 135 the bonding material so squeezed would tend to “run” or otherwise foul the surface of the substrate 110, or worse, the MEMS chip 115 itself. Significantly, and as can now be readily appreciated by those skilled in the art, when a eutectic or similar bonding material is employed the barrier walls 130, 135 act to contain any bonding material 150 which is so squeezed.

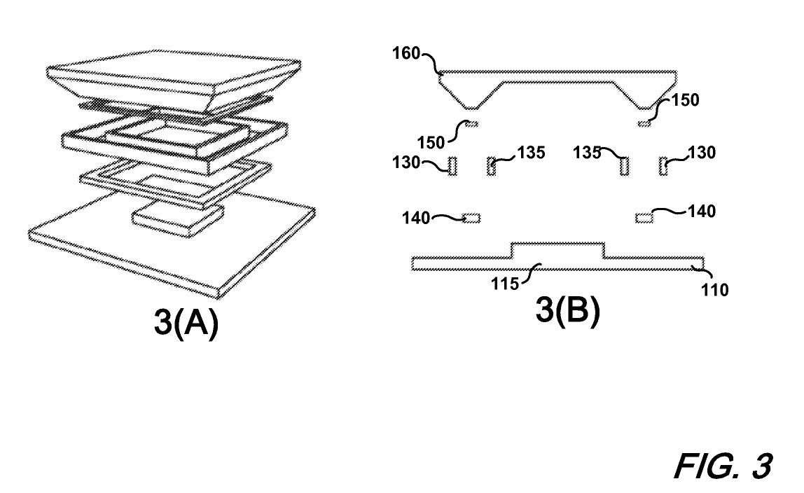

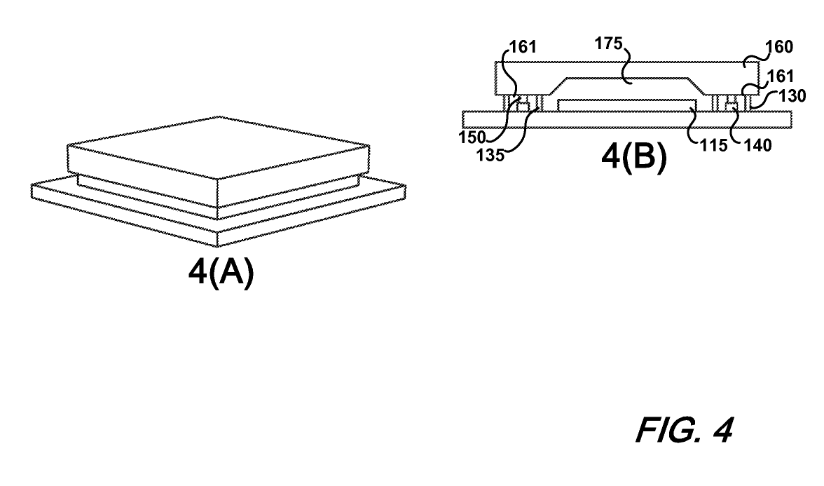

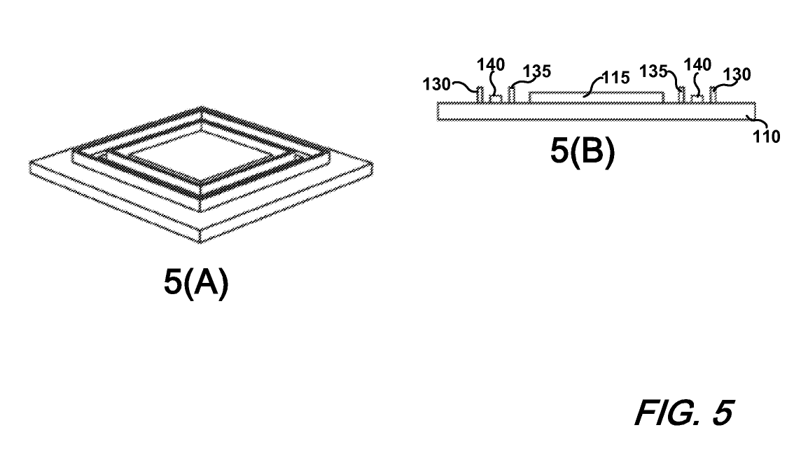

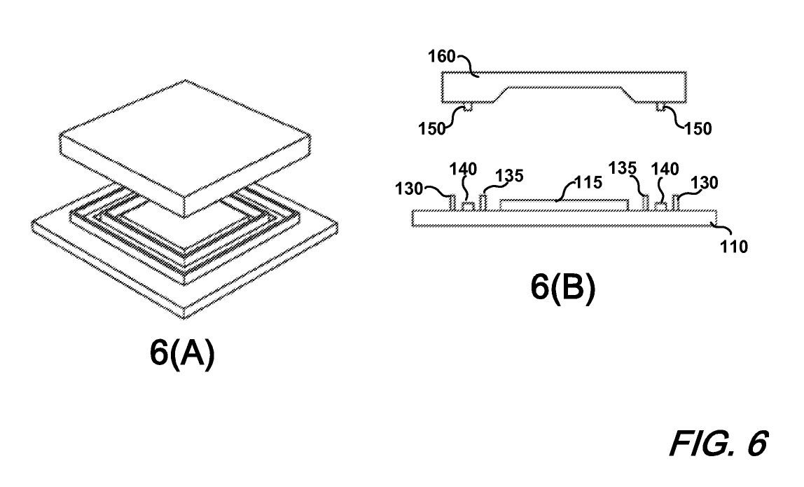

Turning now to FIG. 2(A) and FIG. 2(B) it can be seen how the cap 160 fits together with the structures disposed upon the substrate 110. More particularly, it may be observed that the cap 160 engages the moat region 132 until the bonding material 150 and the bonding block 140 are fully engaged and therefore sealed. When the barrier walls 130, 135 are appropriately sized (as in FIG. 4), they serve as additional mechanical “stops” to the engagement of the cap 160 within the moat. FIGS. 3(A) and 3(B) offer “exploded” views of the components employed.

Those skilled in the art will quickly appreciate that the particular shapes and relative sizes of the components are matters of design choice, and wide variations are possible. In particular, it has been shown in FIGS. 1-3 that the cap engages the moat region upon placement. Such arrangements are advantageously not required according to the present invention.

More particularly, with reference now to FIG. 4, it is shown that the cap 160 does not have such a shape that it engages the moat region. Instead, its bottom, sealing surface 161 is substantially flat so that it uniformly contacts both barrier walls 130, 135 simultaneously. As a result, when the cap 160 is placed upon the barrier walls 130, 135, it is mechanically stopped from further downward movement while still permitting the bonding material 150 to provide an effective seal along the bottom surface of the cap 160 and the length of the bonding pad 140. Still further, the inner barrier wall 130 prevents significant amounts of bonding material 150 from contaminating the cavity 175 in which the MEMS chip 115 becomes encased. Finally, the outer barrier wall 135 prevents significant amounts of bonding material 150 from being displaced onto external surfaces of the substrate 110. While this FIG. 4 shows a preferred embodiment fo the present invention, those skilled in the art will quickly realize that modifications to this preferred embodiment are within the scope of the invention. More particularly, alternatives to the configuration shown in FIG. 4 are shown in FIGS. 5(A), 5(B) and 6(A), 6(B).

As noted earlier, particular gas(ses) are hermetically sealed within the MEMS cavity along with the MEMS device(s). More particularly, a non-flammable gas such as nitrogen or carbon dioxide may be employed, or in a preferred embodiment, an electronegative gas may be permanently sealed within such MEMS cavity.

In particular, and according to the present invention, a strongly electronegative gas such as sulfur hexafluoride (SF₆) in a range of concentrations and pressure(s) is a particularly useful gas for the MEMS cavity. Pressures as low as 0.1 ATM up to and including many ATM are well within the operating range of the present invention. In addition, concentrations as low as 1 PPM may show marked improvement over devices which do not include such an electronegative gas. Finally, while sulfur hexafluoride is particularly disclosed herein, it is to be understood that other electronegative gases or other halogen containing gases may be used in combination with other gases such as FREONS, Carbon Tetrachloride (CCl₄), HALONS (chloro-fluorohydrocarbons), or dicarbon hexafluoride.

Advantageously, the MEMS package described according to the present invention permits the MEMS to withstand relatively high electrical voltages with very small gaps. As such, MEMS switches constructed and packaged according to the present invention operate over a very broad range of electrical voltages—as high as 500 volts with a gap of only a few microns.

At this point, while the present invention has been shown and described using some specific examples, those skilled in the art will recognize that the teachings are not so limited. Accordingly, the invention should be only limited by the scope of the claims attached hereto.

What is claimed is:

1. A Microelectromechanical (MEMS) package comprising:
a MEMS device; and
a sealed cavity, in which the MEMS device is placed;
CHARACTERIZED IN THAT:
the sealed cavity includes a quantity of an electronegative gas.

2. The MEMS package of claim 1
FURTHER CHARACTERIZED IN THAT:
the sealed cavity includes a quantity of a gas chosen from the group consisting of nitrogen, carbon dioxide, halogenated hydrocarbons, sulfur hexafluoride, FREONS, Carbon Tetrachloride, HALONS or dicarbon hexafluoride and combinations thereof.

3. The MEMS package of claim 1
FURTHER CHARACTERIZED IN THAT:
the sealed cavity contains from 1 to 100% by volume sulfur hexafluoride.

4. The MEMS package of claim claim 3
FURTHER CHARACTERIZED BY:
the sealed cavity is pressurized to a pressure of 0.1 to 10.0 Atmospheres.

5. A micro-electro-mechanical system (MEMS) comprising:
a MEMS element positioned within a hermetically sealed cavity
CHARACTERIZED IN THAT:
the sealed cavity contains a quantity of an electronegative gas.

6. The MEMS of claim 5:
FURTHER CHARACTERIZED IN THAT:
the electronegative gas comprises sulfur hexafluoride.

7. The MEMS of claim 5
FURTHER CHARACTERIZED IN THAT:
the hermetically sealed cavity includes a quantity of a gas chosen from the group consisting of nitrogen, carbon dioxide, halogenated hydrocarbons, sulfur hexafluoride, FREONS, Carbon Tetrachloride, HALONS or dicarbon hexafluoride and combinations thereof.

8. The MEMS of claim 5 wherein said cavity contains from 1% to 100% by volume sulfur hexafluoride gas.

9. The MEMS of claim 5 wherein said MEMS includes a switch that withstands high voltages.

10. A MEMS package comprising:
a substrate provided with a MEMS element thereon;
a first barrier wall disposed upon the substrate and surrounding the MEMS element;
a second barrier wall disposed upon the substrate and surrounding the first barrier wall;
a cap overlying a top surface of said first barrier wall and said second barrier wall such that a cavity is defined containing said MEMS element.

11. The MEMS package of claim 10 wherein said cap is affixed and said cavity is hermetically sealed.

12. The MEMS package of claim 11 further comprising:
a moat region defined as the area between the inner barrier wall and the outer barrier wall; and
a sealant disposed within the moat region for sealing the cap.

13. The MEMS package of claim 11 further comprising:
a bonding pad disposed within the moat region, said bonding pad being affixed to the cap through the effect of the sealant.

14. The MEMS package of claim 12 wherein said cap includes a stepped region which engages the first barrier wall and the second barrier wall when the cap is sealed.

15. A micro-electromechanical-system (MEMS) package comprising:
a means for structurally supporting the MEMS device;
a means for hermetically covering the MEMS device;
a means for sealing the heremetic covering means to the substrate

16. The MEMS package according to claim 15 further comprising:
a means for preventing the sealing means from intruding into the hermetically covered regions.

17. The MEMS package according to claim 16 further comprising:
a means for preventing the sealing means from intruding onto undesirable surfaces of the substrate.

18. The MEMS package according to claim 16 further comprising:
a means for mechanically fixing the physical position of the hermetically covering means relative to the structural supporting means.

19. The MEMS package according to claim 15 further comprising:
a quantity of an electronegative gas contained within the hermetically covered region.

20. The MEMS package according to claim 19 further comprising:
a fixed quantity of a gas within the cavity region, said gas chosen from the group consisting of nitrogen, carbon dioxide, halogenated hydrocarbons, sulfur hexafluoride, FREONS, Carbon Tetrachloride, HALONS or dicarbon hexafluoride and combinations thereof.

21. A MEMS package comprising:
a substrate;
a first barrier wall disposed upon the substrate;
a second barrier wall disposed upon the substrate such that a region is defined between the first barrier wall and the second barrier wall;
a cap overlying the first barrier wall, the second barrier wall and the region between the first barrier wall and the second barrier wall such that a cavity region is defined by the first barrier wall, the substrate and the cap wherein said cap engages the region between the first barrier wall and the second barrier wall and the cavity region; and
a MEMS device positioned within the cavity region.

22. The MEMS package according to claim 21 further comprising:
a fixed quantity of a gas within the cavity region, said gas chosen from the group consisting of nitrogen, carbon dioxide, halogenated hydrocarbons, sulfur hexafluoride, FREONS, Carbon Tetrachloride, HALONS or dicarbon hexafluoride and combinations thereof.

23. The MEMS package according to claim 22 wherein at least of one of the barrier walls is in physical contact with the cap.

24. The MEMS package according to claim 22 further comprising:
a bonding pad disposed in the region between the first barrier wall and the second barrier wall, said bonding pad being bonded to the cap such that at least a portion of the cavity region is hermetically sealed.

25. The MEMS package according to claim 24 wherein at least one of the barrier walls are sized to prevent further downward movement of the cap.

26. The MEMS package according to claim 22 wherein the fixed quantity of gas includes at least 1 PPM sulfur hexafluoride.
